(19) United States
(12) Patent Application Publication
(10) Pub. No.: US 2011/0006717 A1
(43) Pub. Date: Jan. 13, 2011

(54) Method for Monitoring the Condition of a Commutator of an Electric Motor

(76) Inventors: Christos Kyrtsos, Beverly Hills, MI (US); Kenneth G. Brown, Township, MI (US); Shani Allison, Novi, MI (US)

Correspondence Address: MACMILLAN, SOBANSKI & TODD, LLC, ONE MARITIME PLAZA - FIFTH FLOOR, 720 WATER STREET, TOLEDO, OH, 43604, US

(21) Appl. No.: 12/499,962

(22) Filed: Jul. 9, 2009

(51) Int. Cl. G01R 31/02

(52) U.S. Cl. 318/490

(57) ABSTRACT

A method for detecting a packed slot condition in a commutator of an electric motor comprising the steps of: (a) providing an electric motor having a commutator, the commutator having a plurality of segments separated from each other by a slot; (b) monitoring the current going through the electric motor; (c) determining if the current going through the electric motor being monitored in step (b) has changed from a preset value; and (d) providing a signal to indicate that the current going through the electric motor has changed to thereby detect for a packed slot in the commutator.

### BACKGROUND OF THE INVENTION

This invention relates in general to electric motors and in particular to a method for monitoring the condition of a commutator for such an electric motor.

Some direct current (DC) electric motors have a commutator located on an end face of the rotor of the motor. The commutator is typically comprised of a plurality of wedge-shaped segments, each separated by a small gap or slot. The commutator segments are coupled to the armature windings of the rotor, as is well-known in the art. Usually, carbon brushes, which may have copper powder mixed in to improve conductivity, are biased against the commutator, also as is well-known in the art.

In a common method of manufacturing such an end-face commutator, an end face of the rotor is made of copper, but without the aforementioned segments. Slots are then machined in the copper to form the wedge-shaped segments of the commutator. Alternatively, for some motor usually for smaller equipment, the commutator segments may sometimes be stamped directly into the metal of the end face of the rotor. As is known, each conducting segment on the armature of the commutator is insulated from adjacent segments by a suitable insulating material.

Typically, the segments of the commutator are held onto the shaft of the rotor using a dovetail shape on the edges or underside of each segment, using insulating wedges around the perimeter of each commutation segment. Due to the high cost of repairs, for smaller motors the segments are typically crimped permanently in place and cannot be removed. Thus, when the motor fails it is simply discarded and replaced. On larger motors it is economical to be able to replace individual damaged segments, and so the end-wedge can be unscrewed and individual segments removed and replaced.

A problem which may occur during operation of the DC motor is that the slots between the segments of the commutator may become filled or packed with water and dirt from the environment and/or from the dust and pieces from the material of the brushes, referred to as carbon fouling since the brushes nowadays are typically made from a “softer” carbon material though may be made also from a “harder” copper material, disposed adjacent thereto as the brushes wear away. Because the slots are designed to electrically isolate the commutator segments from one another, a filled slot can cause shorting between the segments which changes the resistance in the armature winding of the motor and in turn reduces the performance and efficiency of the motor. Unfortunately, unless the motor is removed and inspected, there usually is no way to detect if the efficiency of the motor has been affected by one or more of the slots between the segments of the commutator becoming filled or packed with dirt and/or dust or particles from the brushes. As a result, typically motors will eventually lose efficiency over time or fail and need to be replaced or repaired.

Thus, it would be desirable to provide a method for monitoring the condition of a commutator of an electric motor without having to remove or disassemble the motor yet is relatively simple and inexpensive.

### SUMMARY OF THE INVENTION

This invention relates to a method for monitoring the condition of a commutator for an electric motor and in particular, for detecting a packed slot condition of the commutator. According to one embodiment, the method for detecting a packed slot condition in a commutator of an electric motor comprising the steps of: (a) providing an electric motor having a commutator, the commutator having a plurality of segments separated from each other by a slot; (b) monitoring the current going through the electric motor; (c) determining if the current going through the electric motor being monitored in step (b) has changed from a preset value; and (d) providing a signal to indicate that the current going through the electric motor has changed to thereby detect for a packed slot in the commutator.

According to another embodiment, the method for detecting a packed slot condition in a commutator of an electric motor comprising the steps of: (a) providing an electric motor having a commutator and an armature, the commutator having a plurality of segments separated from each other by a slot; (b) monitoring the current going through the electric motor; (c) determining if the current going through the electric motor being monitored in step (b) has decreased or increased from a preset value thereby indicating an increase or decrease, respectively, in a resistance of the armature of the electric motor; and (d) providing a signal to indicate that the current going through the electric motor has changed to thereby detect for a packed slot in the commutator.

According to yet another embodiment, the method for detecting a packed slot condition in a commutator of a brushed DC electric motor comprising the steps of: (a) providing a brushed DC electric motor having a commutator and an armature, the commutator having a plurality of segments separated from each other by a slot; (b) monitoring the current going through the electric motor; (c) determining if the current going through the electric motor being monitored in step (b) has decreased or increased from a preset value thereby indicating an increase or decrease, respectively, in a resistance of the armature of the electric motor; and (d) providing a signal to indicate that the current going through the electric motor has changed to thereby detect for a packed slot in the commutator, the signal being one of a visual, audio or diagnostic trouble code signal.

Other advantages of this invention will become apparent to those skilled in the art from the following detailed description of the preferred embodiments, when read in light of the accompanying drawings.

### BRIEF DESCRIPTION OF THE DRAWINGS

FIG. 1 is a side view of a portion of an embodiment of a prior art DC electric motor.

FIG. 2 is an end view of a portion of the prior art DC electric motor illustrated in FIG. 1, showing an end face of a commutator thereof.

FIG. 3 is a flow chart of an embodiment of a method for monitoring the condition of the commutator for a DC electric motor according to the invention.

### DETAILED DESCRIPTION OF THE PREFERRED EMBODIMENTS

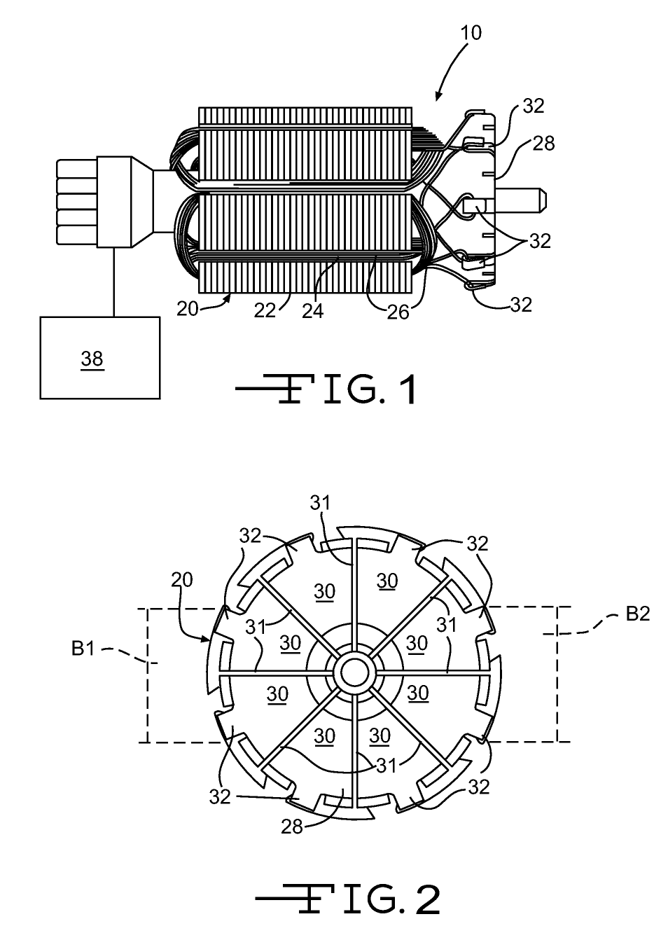

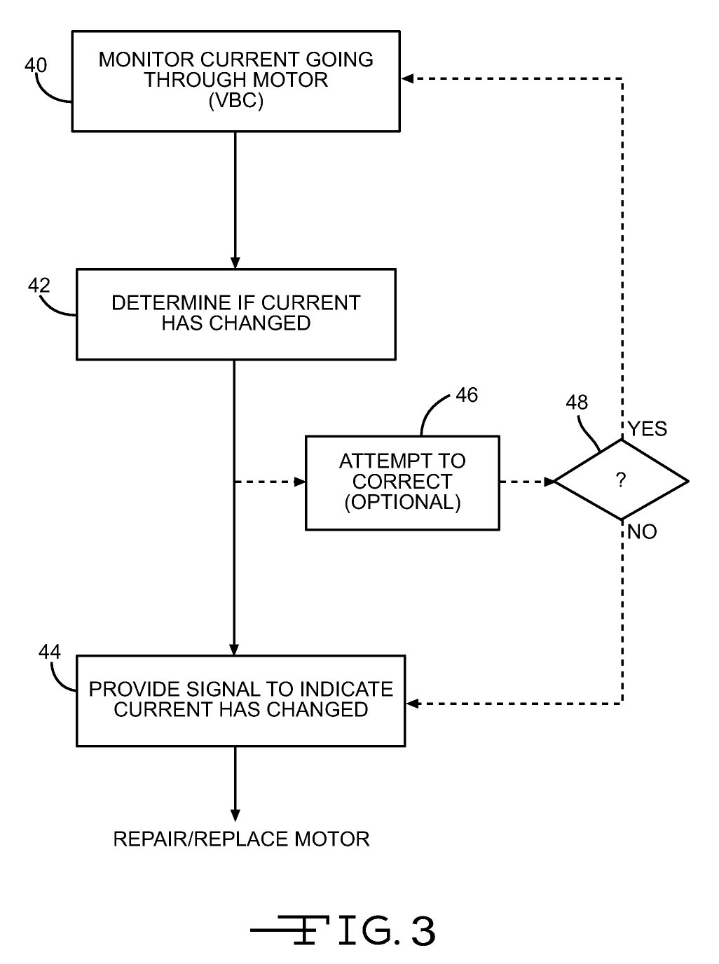

Referring first to prior art FIGS. 1 and 2, there is illustrated a rotor 20 for an electric motor, indicated generally at 10, such as for example, a small fuel pump motor, a blower motor, or any other like motor, will be described. The embodiment of the electric motor 10 illustrated herein is generally the same as that shown in FIGS. 1 and 2 of U.S. Pat. No. 5,776,261 to Panyard et al., the disclosure of which is incorporated herein by reference in entirety, and illustrates a brushed DC electric motor. The general structure and operation of the illustrated brushed DC electric motor 10 is conventional in the art. Thus, only those portions of the brushed DC electric motor 10 which are necessary for a full understanding of this invention will be explained and illustrated in detail. Also, although this invention will be described and illustrated in connection with the particular embodiment of the electric motor 10 disclosed herein, it will be appreciated that this invention may be used in connection with other suitable kinds of electric motors. For example, the invention may be used in connection with other kinds of electric motors if so desired having a commutator with segments and slots between them.

In the illustrated embodiment, the rotor 20 of the electric motor 10 includes a generally cylindrical armature portion 22 having a plurality of slots 24 formed therein. Armature windings 26 are located within and extend out of the ends of slots 24 of the armature portion 22. At an end of rotor 20 (right end of the rotor 20 viewed in prior art FIG. 1), is a commutator 28.

The commutator 28 comprises a plurality of wedge-shaped segments 30 made of an electrical conductor such as copper. In the illustrated embodiment, the commutator 28 includes eight of such wedge-shaped segments 30. Each pair of the segments 30 is separated by a slot 31 and each segment 30 includes a terminal 32. Alternatively, the construction of the commutator 30 may be other than illustrated if so desired.

At the terminals 32, the segments 30 are electrically coupled to armature windings 26. When the rotor 20 is assembled into the electric motor 10, carbon brushes (shown in phantom in prior art FIG. 2 at B1 and B2), are biased against commutator 28. The construction and operation of the electric motor 10 thus far described is conventional in the art.

Referring now to FIG. 3, there is illustrated a schematic diagram of an embodiment of a method for monitoring the condition of the commutator for a preferably brushed DC electric motor, such as the commutator 28 of the electric motor 10 illustrated and described above in connection with FIGS. 1 and 2. As shown therein, in step 40 the current going through the associated electric motor 10 is monitored by suitable electronic control unit or electronic current monitoring device, schematically shown in FIG. 1 at 38 being operatively connected to the electric motor 10. Such a suitable current monitoring device 38 can be any suitable type of device which is capable of preferably continuously monitoring the current going through the associated electric motor 10.

Next, in step 42, the current monitoring device 38 determines if the current going through the associated electric motor 10 has changed from a normal or preset value. Preferably, the current monitoring device 39 determines if the current going through the associated electric motor 10 has decreased. This is because measuring the resistance across the electric motor 10 as it rotates will produce a fairly constant resistance except when the brushes short to adjacent commutator segments at which point the current will drop because the effective resistance has increased, the effective resistance being equal to the sum of the resistances for each commutator slot. In mathematical terms, this is expressed by the following equation: I=(V_{applied}−V_{cemf})/Rₐᵣₘₐₜᵤᵣₑ, where I is the current going through the electric motor, V_{applied} is the voltage across the electric motor, V_{cemf} is the counter electromotive force (EMF) or back EMF, and Rₐᵣₘₐₜᵤᵣₑ is the armature resistance from the windings of the electric motor. Thus, it can be seen that the supply current will decrease or drop when the armature resistance increases as will be the case if one or more of the slots of the commutator causes a short due to the slot(s) becoming packed or filled with dirt and/or dust or particles from the brushes. Alternatively, during step 42, the current monitoring device 38 can also determine if the current going through the associated electric motor 10 has increased so as to also indicate that the supply current has changed as may be the case where one or more of the slots of the commutator causes a short due to the slot(s) becoming packed or filled with dirt and/or dust or particles from the brushes.

Next, in step 44, a signal is produced by the current monitor device 38 to indicate that the current going through the electric motor 10 has changed. The signal may be any suitable type of signal, such as a visual signal, and audio signal, or both. In the case of an electric motor used in a motor vehicle, the signal could be a visual signal or light on the dashboard of the vehicle, an audio signal transmitted through the vehicle's sound speakers, or both if so desired. Once the signal is provided in step 44, the user can then be alerted to have the electric motor looked at and serviced to determine if it can be repaired or not. Preferably, the method will provide an early detection system to indicate the “health” or condition of the electric motor 10.

As shown in FIG. 3, an optional step 46 may be performed following step 42 if so desired. In optional step 46, if the current has changed an attempt by the current monitoring means can be performed to clean or burn off the dirt, dust or particles in the slot(s) of the commutator preferably without removal of the motor. This can be accomplished for example by increasing the current (by increasing the voltage applied), to effectively increase the speed of the motor to attempt to clean or burn off the dirt or dust in the slot(s). If step 46 is successful as shown in step 48 so that the current through the electric motor 10 returns to its normal value, the method returns to step 40. If step 46 is not successful as shown in step 48, the method proceeds to step 44. Alternatively, optional step 46 can be performed following step 44 and if successful, can provide a signal to indicate that the current through the electric motor has been corrected.

One suitable type of current monitoring device 38 can be a vehicle's voltage blower controller (VBC). The VBC can be found in some vehicles having an automatically controlled vehicle climate system and operates to control the blower motor for the system by changing the voltage applied to the motor according to preset values. Thus, in accordance with the present invention, the VBC, shown as being used in step 40 of FIG. 3, could be utilized to monitor the current through the vehicle's associated electric blower motor, which can be similar to the electric motor 10. In the case of a filled commutator slot in the blower motor 10, the VBC could be adapted to generate a signal in step 44 to indicate a change, i.e., decrease or increase, in the current through the motor in prior step 42. Alternatively, in optional step 46, the VBC can attempt to correct the problem as described above. In either case, the method using the VBC could be useful as an early detection method or as a diagnostic tool to create a diagnostic trouble code (DTC), to detect and indicate when one or more commutator slots have become packed and created a short which affects the efficiency of the associated electric motor 10.

As discussed above, the method of the invention can be used with the brushed DC electric motor 10 illustrated and described above in connection with FIGS. 1 and 2. However, in the broadest sense of the invention, the method of the invention can be used in connection with any kind of an electric motor having a commuter with slots formed therein which may become packed or filled with dirt or dust during use such that the motor supply current will change as the slots become packed or filled. Typically, this will include at least DC and universal electric motors. Also, as discussed above, the method preferably detects a change (either an increase or a decrease) in the current going through the associated electric motor to indicate that the armature resistance has changed as will be the case if one or more of the slots of the commutator causes a short due to the slot(s) becoming packed or filled with dirt and/or dust or particles from the brushes. Alternatively, other methods of detection may also be used in the method of detection of the present invention to indicate that one or more of the slots of the commutator has caused a short due to the slot(s) becoming packed or filled with dirt and/or dust or particles from the brushes. Such other methods of detection may include spectral analysis, vibration, and heat resulting from the shorting of the commutator slots or sparking thereof.

One advantage of the embodiments of the present invention is that the method of the invention is capable of providing an early warning of the “health” of the associated electric motor without removal of the motor. The method of the present invention can readily detect a short in the motor early on when the short is not solid (i.e., commutator slot not fully packed), and can attempt to correct the problem by increasing the voltage which increase the speed and current of the motor, which can clean or burn off the dirt, dust or particles in the slot(s) of the commutator without requiring the removal of the motor. In the case of electric motors used in vehicles, the method of the invention is especially convenient since such motors are typically not readily accessible for inspection. As discussed above, the method of the present invention can provide an associated and appropriate signal to indicate that the current through the motor has changed, which can be a visual, audio and/or DTC signal, and/or the method can optionally attempt to correct the problem as described above.

In accordance with the provisions of the patent statutes, the principle and mode of operation of this invention have been described and illustrated in its preferred embodiments. However, it must be understood that this invention may be practiced otherwise than as specifically explained and illustrated without departing from its spirit or scope.

What is claimed is:

1. A method for detecting a packed slot condition in a commutator of an electric motor comprising the steps of:
(a) providing an electric motor having a commutator, the commutator having a plurality of segments separated from each other by a slot;
(b) monitoring the current going through the electric motor;
(c) determining if the current going through the electric motor being monitored in step (b) has changed from a preset value; and
(d) providing a signal to indicate that the current going through the electric motor has changed to thereby detect for a packed slot in the commutator.

2. The method for detecting a packed slot condition in a commutator of an electric motor of claim 1 wherein the electric motor is a brushed DC electric motor.

3. The method for detecting a packed slot condition in a commutator of an electric motor of claim 1 wherein step (c) includes the step of determining if the current going through the electric motor has decreased thereby indicating an increase in a resistance of an armature of the electric motor.

4. The method for detecting a packed slot condition in a commutator of an electric motor of claim 1 wherein step (c) includes the step of determining if the current going through the electric motor has increased thereby indicating a decrease in a resistance of an armature of the electric motor.

5. The method for detecting a packed slot condition in a commutator of an electric motor of claim 1 wherein step (d) includes the step of providing at least one of a visual and an audio signal.

6. The method for detecting a packed slot condition in a commutator of an electric motor of claim 1 wherein step (d) includes the step of providing a diagnostic trouble code signal.

7. The method for detecting a packed slot condition in a commutator of an electric motor of claim 1 wherein the electric motor in step (a) is a vehicle electric blower motor.

8. The method for detecting a packed slot condition in a commutator of an electric motor of claim 7 wherein the vehicle electric blower motor includes a voltage blower controller which is used in step (b) to monitor the current going through the electric blower motor.

9. The method for detecting a packed slot condition in a commutator of an electric motor of claim 1 wherein following step (c) further including the step of attempting to correct the change in the voltage of the electric motor.

10. The method for detecting a packed slot condition in a commutator of an electric motor of claim 9 wherein the step of attempting to correct the change in the voltage of the electric motor is performed by increasing the current applied to the electric motor.

11. A method for detecting a packed slot condition in a commutator of an electric motor comprising the steps of:
(a) providing an electric motor having a commutator and an armature, the commutator having a plurality of segments separated from each other by a slot;
(b) monitoring the current going through the electric motor;
(c) determining if the current going through the electric motor being monitored in step (b) has decreased or increased from a preset value thereby indicating an increase or decrease, respectively, in a resistance of the armature of the electric motor; and
(d) providing a signal to indicate that the current going through the electric motor has changed to thereby detect for a packed slot in the commutator.

12. The method for detecting a packed slot condition in a commutator of an electric motor of claim 11 wherein the electric motor is a brushed DC electric motor.

13. The method for detecting a packed slot condition in a commutator of an electric motor of claim 11 wherein step (d) includes the step of providing at least one of a visual and audio.

14. The method for detecting a packed slot condition in a commutator of an electric motor of claim 11 wherein step (d) includes the step of providing a diagnostic trouble code signal.

15. The method for detecting a packed slot condition in a commutator of an electric motor of claim 11 wherein the electric motor in step (a) is a vehicle electric blower motor.

16. The method for detecting a packed slot condition in a commutator of an electric motor of claim 15 wherein the vehicle electric blower motor includes a voltage blower controller which is used in step (b) to monitor the current going through the electric blower motor.

17. The method for detecting a packed slot condition in a commutator of an electric motor of claim 11 wherein following step (c) further including the step of attempting to correct the change in the voltage of the electric motor.

18. The method for detecting a packed slot condition in a commutator of an electric motor of claim 17 wherein the step of attempting to correct the change in the voltage of the electric motor is performed by increasing the current applied to the electric motor.

19. A method for detecting a packed slot condition in a commutator of a brushed DC electric motor comprising the steps of:
(a) providing a brushed DC electric motor having a commutator and an armature, the commutator having a plurality of segments separated from each other by a slot;
(b) monitoring the current going through the electric motor;
(c) determining if the current going through the electric motor being monitored in step (b) has decreased or increased from a preset value thereby indicating an increase or decrease, respectively, in a resistance of the armature of the electric motor; and
(d) providing a signal to indicate that the current going through the electric motor has changed to thereby detect for a packed slot in the commutator, the signal being one of a visual, audio or diagnostic trouble code signal.

20. The method for detecting a packed slot condition in a commutator of a brushed DC electric motor of claim 19 wherein the brushed DC electric motor in step (a) is a vehicle electric blower motor having a voltage blower controller which is used in step (b) to monitor the current going through the brushed DC electric blower motor.
